(19) United States
(12) Patent Application Publication
(10) Pub. No.: US 2009/0072294 A1
(43) Pub. Date: Mar. 19, 2009

(54) Method of manufacturing a non-volatile memory device

(75) Inventors: Sang-Ryol Yang, Hwaseong-si (KR); Sung-Kweon Baek, Suwon-si (KR); Si-Young Choi, Seongnam-si (KR); Bon-Young Koo, Suwon-si (KR); Ki-Hyun Hwang, Seongnam-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/974,636

(22) Filed: Oct. 15, 2007

(30) Foreign Application Priority Data
Oct. 16, 2006 (KR) 10-2006-0100243

(51) Int. Cl. H01L 29/788; H01L 21/336

(52) U.S. Cl. 257/321; 438/264; 257/E29.3; 257/E21.422

(57) ABSTRACT

A method of manufacturing a non-volatile memory device employing a relatively thin polysilicon layer as a floating gate is disclosed, wherein a tunnel oxide layer is formed on a substrate and a polysilicon layer having a thickness of about 35 Å to about 200 Å is then formed on the tunnel oxide layer using a trisilane (Si₃H₈) gas as a silicon source gas. The tunnel oxide layer and the polysilicon layer are then patterned into a tunnel oxide layer pattern and a polysilicon layer pattern, respectively. A dielectric layer and a conductive layer corresponding to a control gate are subsequently formed on the polysilicon layer pattern. The polysilicon layer is formed using trisilane (Si₃H₈) gas as a result of which the polysilicon layer may be formed to have a relatively thin thickness while maintaining a thickness uniformity and realizing a superior morphology thus producing a floating gate having enhanced performance.

### CROSS-REFERENCE TO RELATED APPLICATION

This application claims priority under 35 U.S.C. § 119 to Korean Patent. Application No. 2006-100243 filed on Oct. 16, 2006 in the Korean Intellectual Property Office (KIPO), the contents of which are herein incorporated by reference in their entirety.

### BACKGROUND OF THE INVENTION

1. Field of the Invention

Exemplary embodiments of the present invention relate to methods of manufacturing a non-volatile memory device. More particularly, exemplary embodiments of the present invention relate to methods of manufacturing a non-volatile memory device having a floating gate that includes polysilicon.

2. Description of the Related Art

A non-volatile memory device may permanently retain its data even when power to the device is removed or interrupted. In addition, a non-volatile memory device may write and erase electric data advantageously. Thus, non-volatile memory devices are widely used to store data in mobile electronic devices. Recently, non-volatile memory devices are increasingly being widely employed in electronic devices such as digital cameras, MPEG audio layer 3 (MP3) players, memories of cellular phones, etc.

A unit cell of a typical non-volatile memory device includes a vertically aligned gate structure having a floating gate. Particularly, a gate structure of a typical non-volatile memory device includes a floating gate, a dielectric layer, and a control gate sequentially formed on a tunnel oxide layer.

As a design rule of non-volatile memory devices has progressively been decreased, a distance between adjacent gates of the devices also has been narrowed. Thus, an interference coupling between the adjacent gates of a single device has become increasingly large. In response, a thickness of the floating gate has been gradually reduced to prevent an increase of the interference coupling between adjacent gates

A polysilicon layer is generally used as the floating gate in such devices. To form the polysilicon layer, an amorphous silicon layer is generally formed using a silane (SiH₄) gas. The amorphous silicon layer is then crystallized into the polysilicon layer. However, in a case where a silane (SiH₄) gas is used to form the polysilicon layer, the resulting polysilicon layer may be inferior in its morphology and thickness uniformity.

Particularly, a size of a silicon grain of a polysilicon layer that has been obtained from an amorphous silicon layer formed using silane (SiH₄) gas may be relatively large. In addition, a surface of such a silicon grain may have an undesirable shape. Thus, the morphology of such a polysilicon layer comprised of such silicon grains typically is relatively poor. In this case, a cleaning solution used in a subsequent cleaning process may infiltrate the tunnel oxide layer that is located under the polysilicon layer, such infiltration occurring through a grain boundary of the polysilicon layer or through a crack of the polysilicon layer. Thus, the cleaning solution may damage the tunnel oxide layer resulting in a defective or poorly performing memory device.

In addition, in the conventional process a thickness of the amorphous silicon layer may become irregular while the amorphous silicon layer is formed on the tunnel oxide layer, sometimes resulting, for example, in a relatively thin thickness of below about 200 □Å when using the silane (SiH₄) gas. That is, the thickness of the amorphous silicon layer may become larger or smaller than a required or desired uniform thickness. In a case where the amorphous silicon layer is formed extremely thin, the tunnel oxide layer may be exposed through the amorphous silicon layer resulting in a defective memory device.

To overcome the above problems with conventional fabrication techniques, it has been found that, a passivation layer may be further formed on the tunnel oxide layer so as to prevent damage to the tunnel oxide layer that is located under the polysilicon layer in cases where the morphology and the thickness and uniformity of the polysilicon layer are inferior as described above.

However, in cases where such a passivation layer is further formed, subsequent processes in manufacturing the non-volatile memory device become complicated. In addition, the cost and/or the time required for manufacturing the non-volatile memory device may be increased by practicing this modified fabrication technique.

These and other problems with and limitations of the above-described techniques are overcome in whole or at least in part by the methods of this invention.

### SUMMARY OF THE INVENTION

Exemplary embodiments of the present invention provide methods of manufacturing a non-volatile memory device including a polysilicon floating gate having a superior morphology and a superior thickness uniformity as compared with such devices prepared according to prior art techniques.

In accordance with an exemplary embodiment of the present invention, there is provided a method of manufacturing a non-volatile memory device. In the method, a tunnel oxide layer is first formed on a suitable substrate. A polysilicon layer having a thickness of about 35 Å to about 200 Å is then formed on the tunnel oxide layer by using a trisilane (Si₃H₈) gas. The tunnel oxide layer and the polysilicon layer are patterned into a tunnel oxide layer pattern and a polysilicon layer pattern, respectively. A dielectric layer and a conductive layer corresponding to a control gate are subsequently formed on the polysilicon layer pattern.

A surface of the polysilicon layer formed according to this invention desirably may have a root-mean-square roughness of about 0.1 nm to about 0.4 nm. To form such a polysilicon layer, an amorphous silicon layer may be formed on the tunnel oxide layer by a low pressure chemical vapor deposition (LPCVD) process. The amorphous silicon layer is then crystallized. The LPCVD process may be performed at a temperature of about 400° C. to about 500° C. and at a pressure of about 100 mTorr to about 1,000 mTorr. The resulting amorphous silicon layer may then be crystallized by thermally treating the amorphous silicon layer at a temperature of about 550° C. to about 900° C. To manufacture a non-volatile memory device in accordance with this invention, a surface of the tunnel oxide layer may be treated with ozone water before the polysilicon layer is formed. The ozone water may include de-ionized water and ozone, and the concentration of the ozone in the water may be about 10 ppm to about 1,000 ppm. To form the tunnel oxide layer pattern and the polysilicon layer pattern, a mask layer pattern partially exposing the polysilicon layer is formed on the polysilicon layer. The polysilicon layer, the tunnel oxide layer and the substrate are then etched by using the mask layer pattern as an etching mask to form a polysilicon layer pattern, a tunnel oxide layer pattern and a trench. An isolation layer is then formed on the structure so as to fill up the trench and such that an upper portion of the isolation layer protrudes from a surface of the substrate and so may be further formed. An upper portion of the isolation layer may also be partially removed such that a sidewall of the polysilicon layer pattern is exposed. The mask pattern is then removed to expose the polysilicon layer pattern. Next, the upper portion of the isolation layer is partially removed by an isotropic etching process. A second polysilicon layer is then formed on the isolation layer and the polysilicon layer pattern. A second polysilicon layer pattern may then be formed by removing a portion of the second polysilicon layer that is disposed higher than an upper surface of the isolation layer. An isolation layer pattern is formed by removing an upper portion of the isolation layer such that sidewalls of the second polysilicon layer pattern are exposed. The isotropic etching process may be performed using a diluted hydrogen fluoride (HF) solution. A cleaning process may be performed on the polysilicon layer pattern after the polysilicon layer pattern is exposed. The cleaning process may be performed using a diluted hydrogen fluoride (HF) solution or a standard clean 1 solution including ammonium hydroxide (NH₄OH), hydrogen peroxide (H₂O₂) and water (H₂O).

According to exemplary embodiments of the present invention, a polysilicon layer having a superior morphology and a superior thickness uniformity relative to those formed by conventional techniques is formed on a tunnel oxide layer by using a trisilane (Si₃H₈) gas such that the polysilicon layer has a thickness of about 35 Å to about 200 Å. In addition, the polysilicon layer having the superior morphology and the superior thickness uniformity according to this invention may reduce damage to the device being fabricated due to chemicals used in subsequent fabrication processes such as a cleaning process and a wet etching process.

### BRIEF DESCRIPTION OF THE DRAWINGS

The above and other features and advantages of the present invention will become readily apparent by reference to the following detailed description when considered in conjunction with the accompanying drawings, wherein:

FIGS. 1 to 6 are schematic cross-sectional views illustrating a method of manufacturing a non-volatile memory device in accordance with one exemplary embodiment of the present invention;

FIGS. 7 to 11 are schematic cross-sectional views illustrating a method of manufacturing a non-volatile memory device in accordance with another exemplary embodiment of the present invention;

FIGS. 12 to 19 are schematic cross-sectional views illustrating a method of manufacturing a non-volatile memory device in accordance with another exemplary embodiment of the present invention;

FIG. 20 is a graph illustrating an atomic force microscope (AFM) measurement of a polysilicon layer formed using a silane (SiH₄) gas according to a conventional technique; and

FIG. 21 is a graph illustrating an AFM measurement of a polysilicon layer formed using a trisilane (Si₃H₈) gas in accordance with an embodiment of the present invention.

### DESCRIPTION OF THE EMBODIMENTS

The present invention is described more fully hereinafter with reference to the accompanying drawings, in which exemplary embodiments of the present invention are shown. The present invention may, however, be embodied in many different forms and should not be construed as limited to the exemplary embodiments set forth herein. Rather, these exemplary embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will also be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the present invention are described herein with reference to cross-sectional illustrations that are schematic illustrations of idealized embodiments (and intermediate structures) of the present invention. As such, variations from the shapes of the illustrations as a result, for example, of manufacturing techniques and/or tolerances, are to be expected. Thus, exemplary embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

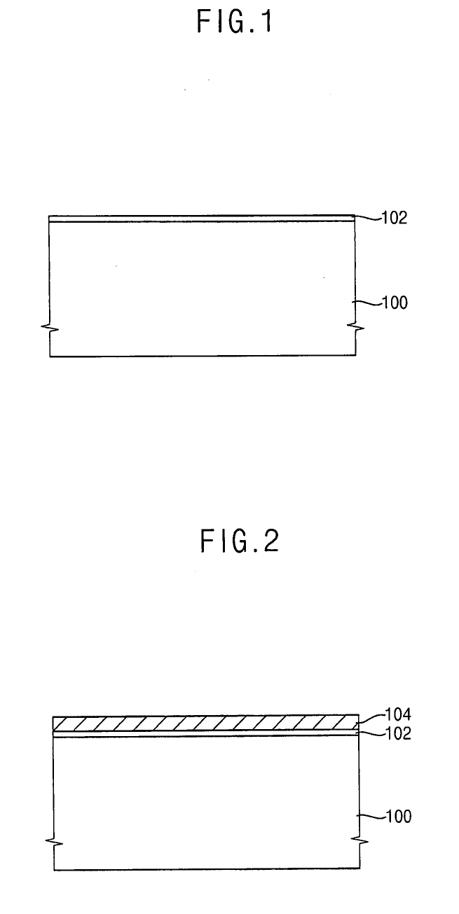

FIGS. 1 to 6 are schematic cross-sectional views illustrating a method of manufacturing a non-volatile memory device in accordance with an exemplary embodiment of the present invention.

Referring to FIG. 1, a tunnel oxide layer 102 is formed on a suitable substrate 100 such as, for example, a silicon wafer.

The tunnel oxide layer 102 may be formed by a thermal oxidation process. Alternatively, the tunnel oxide layer 102 may be formed by a chemical vapor deposition (CVD) process or an atomic layer deposition (ALD) process. A method of forming the tunnel oxide layer 102 is, however, not intended to limit the present invention.

A surface of the tunnel oxide layer 102 may be treated with ozone water. Without limiting the scope of this invention, it is believed that the ozone water may form a hydroxyl radical (—OH) on the surface of the tunnel oxide layer 102. The presence of such hydroxyl radicals (—OH) on the surface of the tunnel oxide layer 102 may facilitate a polysilicon layer 104 being effectively formed by succeeding processes. Thus, a morphology of the polysilicon layer 104 may be improved.

The ozone water may consist of de-ionized (DI) water including ozone (O₃). A concentration of ozone in the ozone water may be from about 10 ppm to about 1,000 ppm.

Referring to FIG. 2, an amorphous silicon layer 104 having a thickness of from about 35 Å to about 200 Å is formed on the tunnel oxide layer 102 by using a trisilane (Si₃H₈) gas.

The amorphous silicon layer 104 thus formed may be transformed into a polysilicon layer by succeeding processes. The polysilicon layer may serve as a floating gate of a non-volatile memory device.

Recently, a distance between floating gates has progressively decreased as it has become desirable to decrease a design rule of a memory cell. Thus, the potential for a mutual interference between the adjacent floating gates has increased. In cases where a thickness of the floating gate decreases, the mutual interference between adjacent floating gates may also decrease. Thus, the polysilicon layer may preferably be formed to have a thickness of from about 35 Å to about 200 Å in an exemplary embodiment of the present invention.

However, in cases where a required thickness of the polysilicon layer becomes thinner, a morphology and a thickness uniformity of the polysilicon layer formed using a silane (SiH₄) gas become poor. Particularly, in cases where the required thickness of the polysilicon layer becomes small, a size of a silicon grain may increase and a surface of the silicon grain may have an undesirable shape that adversely affects the performance of a memory device incorporating such a component. Thus, the morphology of the resulting polysilicon layer may be considered undesirable. In addition, in cases where the required thickness of the polysilicon layer becomes small, it is difficult to form the polysilicon layer having the required thickness. Thus, the thickness uniformity of the polysilicon layer may also be considered undesirable.

To overcome the above problems, a silicon-containing gas used for forming the amorphous silicon layer 104 that is subsequently transformed into the polysilicon layer may be altered in accordance with the present invention.

Particularly, the amorphous silicon layer 104 is preferably formed using the trisilane (Si₃H₈) gas instead of the conventional silane (SiH₄) gas. In this case, it ha been found that a size of a silicon grain in the polysilicon layer obtained from the amorphous silicon layer 104 formed using the trisilane (Si₃H₈) gas is relatively small, and additionally that a surface of the silicon grain may have a desirable shape. Thus, the morphology of the resulting polysilicon layer may be improved. In addition, the polysilicon layer is continuously and uniformly formed even though the required thickness of the polysilicon layer is relatively small. Thus, the thickness uniformity may be also improved. As a result, the performance of a memory device incorporating such a component may have an improved performance.

To form the amorphous silicon layer 104 that is subsequently transformed into the polysilicon layer having the superior morphology and the superior thickness uniformity, a low pressure chemical vapor deposition (LPCVD) process is performed on the tunnel oxide layer 102 by using the trisilane (Si₃H₈) gas as a sole or at least primary source gas. Thus, the amorphous silicon layer 104 may be formed on the tunnel oxide layer 102 to a thickness of about 35 Å to about 200 Å. Particularly, the LPCVD process may be performed at a temperature of about 400° C. to about 500° C. and at a pressure of about 100 mTorr to about 1,000 mTorr. For example, the LPCVD process may be performed at a temperature of about 450° C. at a pressure of about 200 mTorr.

In some embodiments of this invention, a second source gas may be provided together with the trisilane (Si₃H₈) gas while the amorphous silicon layer 104 is being formed as a way of introducing a controlled concentration of an impurity into the amorphous silicon layer 104. Alternatively, impurities may be implanted into the polysilicon layer after the polysilicon layer is formed. The timing of when the impurities are implanted is normally not critical and is not intended to limit the present invention.

The amorphous silicon layer 104 is then crystallized by subsequent processes so that the amorphous silicon layer 104 may be transformed into the polysilicon layer. Generally, a thermal treatment process performed at a relatively high temperature may be required to crystallize the amorphous silicon layer 104 into the polysilicon layer. However, it has been found that the amorphous silicon layer 104 in accordance with this invention may be transformed into the polysilicon layer by subsequent processes without performing such a relatively high temperature thermal treatment process. Thus, in an exemplary embodiment of the present invention, subsequent processing may be performed at a temperature of about 550° C. to about 900° C. For example, the amorphous silicon layer may be crystallized into the polysilicon layer at a temperature of about 580° C. to about 750° C.

Alternatively, a relatively high temperature thermal treatment process may be performed to crystallize the amorphous silicon layer 104 of this invention into the polysilicon layer.

A root-mean-square (RMS) roughness of the polysilicon layer formed by the above methods in accordance with this invention may be about 0.1 nm to about 0.4 nm. Here, the RMS roughness may be used as a criterion for evaluating the morphology of the polysilicon layer. The morphology of a polysilicon layer formed by the above methods is considered relatively superior as compared with polysilicon layers formed by conventional techniques because the polysilicon layer in accordance with this invention has a RMS roughness of about 0.1 nm to about 0.4 nm.

As a result, a polysilicon layer having a thickness of about 30 Å to about 200 Å, and also having the superior morphology and the superior thickness uniformity may be formed on the tunnel oxide layer 102.

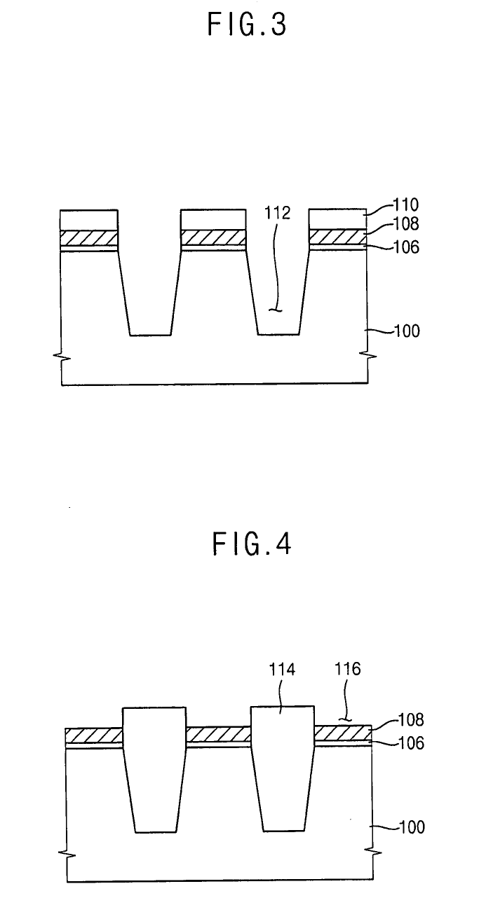

Referring now to FIG. 3, a mask layer (not shown) is formed on the polysilicon layer 104 formed as described above. A photoresist pattern (not shown) is then formed on the mask layer. As described below, a trench 112 is to be formed at a portion of the semiconductor substrate 100 exposed through the photoresist pattern. A second isolation layer pattern 115 (see the description below of FIG. 5) corresponding to a field region is then to be formed in the trench 112. A portion of the semiconductor substrate 100 covered with the photoresist pattern corresponds to an active region.

First, the mask layer is etched using the photoresist pattern as an etching mask so that a mask layer pattern 110 as seen in FIG. 3 may be formed. The photoresist pattern may then be removed by an ashing process and/or a strip process after the mask layer pattern 110 is formed.

The polysilicon layer 104 and tunnel oxide layer 102 are then sequentially etched using the mask layer pattern 110 as an etching mask so that a polysilicon layer pattern 108 and a tunnel oxide layer pattern 106 may be formed on the semiconductor substrate 100 as seen in FIG. 3. The polysilicon layer pattern 108 may be used as a floating gate of a non-volatile memory device in accordance with this invention.

The portion of the semiconductor substrate 100 exposed through the mask layer is then etched using the mask layer pattern 110 as an etching mask so that the trench 112 may be formed. The trench 112 may be formed, for example, by a dry etching process.

A thermal oxide layer (not shown) and an insulating liner (not shown) may then be sequentially formed on an inner surface of the trench 112 after the trench 112 is formed.

Particularly, a thermal oxide layer having a relatively thin thickness may be formed by thermally oxidizing the inner surface of the trench 112. In this manner, a damage to the inner surface of the trench 112 that might be generated by the dry etching process used to form trench 112 may be cured.

The insulating liner preferably having a thickness in the hundreds of angstroms range is then formed on the inner surface of the trench 112 on which the thermal oxide layer has been formed. The insulating liner may reduce a stress in an isolation layer that is subsequently to be formed in the trench 112 by subsequent processes. Such an isolation layer may include a silicon oxide. In addition, the insulating liner may prevent impurities from diffusing into the field region. The insulating liner may be formed using a material having a relatively high etching selectivity with respect to a silicon oxide layer such as a silicon oxide isolation layer. In this case, an etching rate of the insulating liner may be different from an etching rate of the silicon oxide layer at least under certain predetermined etching conditions. For example, the insulating liner may be formed using silicon nitride (SiN) so as to realize the desired etching selectivity.

Referring next to FIG. 4, an isolation layer (not shown) as discussed above is formed on the mask layer pattern 110 (see FIG. 3) and so as to fill up the trench 112. The isolation layer may include an oxide. The oxide, which effectively fills up a gap, may be selected from undoped silicate glass (USG), O₃-tetra-ethyl-ortho-silicate USG (O₃-TEOS USG), high density plasma (HDP) oxide, or similar materials.

For example, the isolation layer may be an HDP oxide layer. In this case, plasma may be generated using a silane (SiH₄) gas, an oxygen (O₂) gas and an argon (Ar) gas as plasma sources. The trench 112 is thereby filled with the HDP oxide effectively filling the trench 112 and forming the HDP oxide layer in the trench 112. Thus, a crack or a void may be avoided in forming the HDP oxide isolation layer.

The isolation layer is then planarized by an etch-back process or a chemical mechanical polishing (CMP) process until the mask layer pattern 110 is exposed. Thus, the first isolation layer pattern 114 may be formed. As illustrated in FIG. 4, the first isolation layer pattern 114 fills up the trench 112. In addition, the first isolation layer may partially protrude from the semiconductor substrate 100 as seen in FIG. 4. The mask layer pattern 110 is then removed. Openings 116 exposing an upper surface of the polysilicon layer pattern 108 are formed by removing the mask layer pattern 110.

Referring next to FIG. 5, the first isolation layer pattern 114 (as seen in FIG. 4) is partially removed such that a sidewall of the polysilicon layer pattern 108 is exposed. Thus, the first isolation layer pattern 114 may be transformed into the second isolation layer pattern 118. This step may be carried out such that tunnel oxide layer pattern 106 is not exposed when the first isolation layer pattern 114 is being partially removed, as seen in FIG. 5.

The first isolation layer pattern 114 may be partially removed, for example, by a dry etching process or a wet etching process.

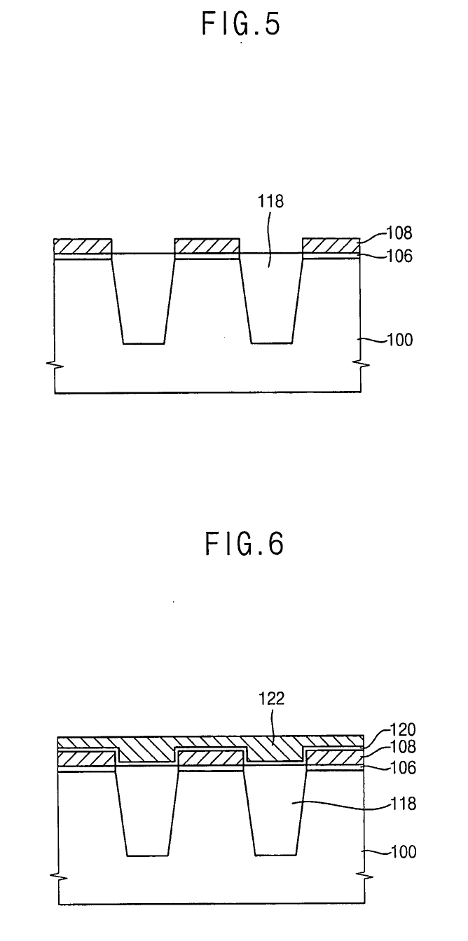

Referring now to FIG. 6, a dielectric layer 120 is formed on the second isolation layer pattern 118 and also on the polysilicon layer pattern 108.

The dielectric layer 120 may be an oxide-nitride-oxide (ONO) layer or a high dielectric constant material layer. The dielectric layer 120 may insulate the polysilicon layer pattern 108 (which corresponds to and functions as a floating gate) from a control gate 122 that is to be formed by succeeding processes.

The ONO (or other high dielectric constant material) layer may be formed for example by an LPCVD process. The high dielectric constant material layer that may be used for dielectric layer 120 instead of the ONO layer may include yttrium oxide (Y₂O₃), hafnium oxide (HfO₂), zirconium oxide (ZrO₂), niobium oxide (Nb₂O₅), barium titanate (BaTiO₃), strontium titanate (SrTiO₃), and similar materials. The high dielectric constant material layer may be formed for example by an ALD process or a CVD process.

The control gate 122 is formed on the dielectric layer 120. For some embodiments, the control gate 122 may advantageously include two layers. For example, a first conductive layer (not shown) including polysilicon doped with impurities may be formed on the dielectric layer 120. A second conductive layer (not shown) including a metal silicide such as, for example, TaSix, CoSix, TiSix, or WSix, may then be formed on the first conductive layer. As a result, a control gate 122 including the first and second conductive layers may be formed.

Accordingly, a planar-shaped non-volatile memory device may thus be formed comprising the tunnel oxide layer pattern 106, the floating gate 108 corresponding to the polysilicon layer pattern, the dielectric layer 120 and the control gate 122 formed on the semiconductor substrate 100. Such a memory device fabricated in accordance with this invention may be expected to demonstrate superior performance relative to comparable devices not prepared according to this invention.

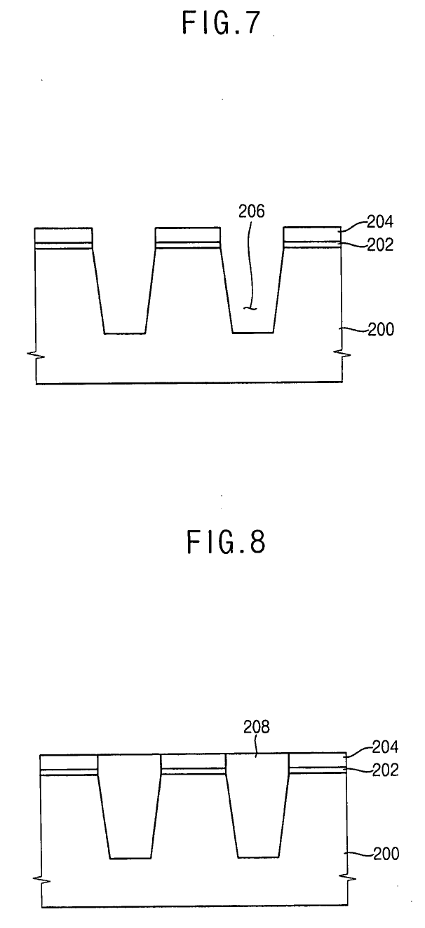

FIGS. 7 to 11 are schematic cross-sectional views illustrating another method of manufacturing a non-volatile memory device in accordance with an exemplary embodiment of the present invention.

Referring to FIG. 7, a pad oxide layer (not shown) and a mask layer pattern 204 are formed on a semiconductor substrate 200. The pad oxide layer is formed by processes substantially the same as those for forming the tunnel oxide layer as described in connection with FIG. 1. Thus, any further explanation of these steps will be omitted.

Here, a field region is formed at a portion of the semiconductor substrate 200 that is exposed through the mask layer pattern 204. An active region is a portion of the semiconductor substrate 200 covered with the mask pattern 204.

The pad oxide layer and the semiconductor substrate 200 are then etched using the mask layer pattern 204 as an etching mask so that a pad oxide layer pattern 202 and a trench 206 may be formed as seen in FIG. 7.

A thermal oxide layer (not shown) and an insulating liner (not shown) may then be sequentially formed by processes substantially the same as those described above in connection with FIG. 3 after the trench 206 has been formed. Thus, any further explanation of these steps will be omitted.

Referring next to FIG. 8, an isolation layer (not shown) is formed on the mask layer pattern 204 and so as to fill up the trench 206. The isolation layer is then planarized by an etch-back process and/or a chemical mechanical polishing (CMP) process until the mask layer pattern 204 is exposed, which transforms the isolation layer into a first isolation layer pattern 208. Processes of forming the first isolation layer pattern 208 are substantially the same as those described above in connection with FIG. 4. Thus, any further explanation of these steps will be omitted.

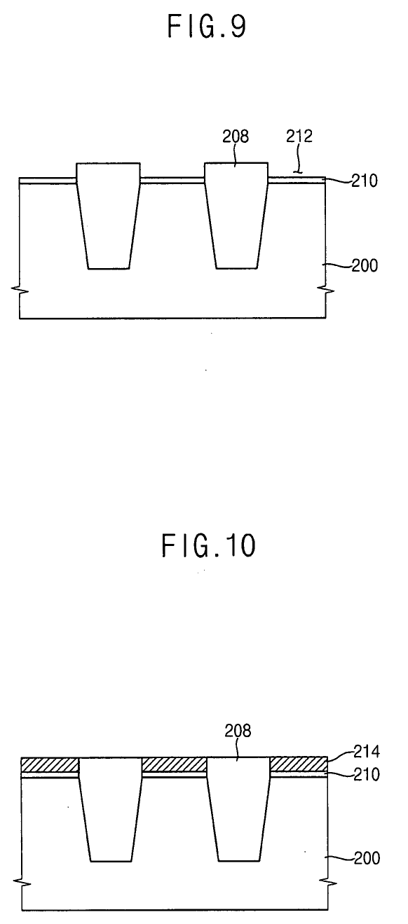

Referring now to FIG. 9, the mask layer pattern 204 (as seen in FIG. 8) is then removed so that the pad oxide layer pattern 202 (as also seen in FIG. 8) may be exposed. Openings 212 (as seen in FIG. 9) are formed by removing the mask layer pattern 204. Particularly, the openings 212 are defined by the first isolation layer pattern 208.

After the pad oxide layer pattern 202 is selectively removed, a tunnel oxide layer pattern 210, defined by the first isolation layer pattern 208, may be formed on the semiconductor substrate 200. Alternatively, in some embodiments, the pad oxide layer pattern 202 may be used as the tunnel oxide layer pattern 210. However, the tunnel oxide layer pattern 210 is preferably formed after the pad oxide layer pattern 202 has been removed. This is because the pad oxide layer pattern 202 may have become damaged by the various etching processes used for forming the pad oxide layer pattern 202, the trench 206, etc.

Referring next to FIG. 10, a polysilicon layer (not shown) is formed on the tunnel oxide layer pattern 210 so as to fill up the openings 212. Particularly, as described and illustrated in connection with FIG. 2, an amorphous silicon layer (not shown) having a thickness of about 35 Å to about 200 Å is formed on the tunnel oxide layer pattern 210 by a low pressure chemical vapor deposition (LPCVD) process. A trisilane (Si₃H₈) gas may advantageously be used as a source gas in such an LPCVD process. The amorphous silicon layer is then crystallized into the polysilicon layer. For example, the amorphous silicon layer may be crystallized by subsequent processes as previously described without an additional thermal treatment process. Processes of forming the polysilicon layer are substantially the same as those described and illustrated in connection with FIG. 2. Thus, any further explanation of these steps will be omitted.

A root-mean-square (RMS) roughness of the polysilicon layer formed by the above processes in accordance with this invention may be about 0.1 nm to about 0.4 nm. Here, the RMS roughness may be used as a criterion for evaluating the morphology of the polysilicon layer. The morphology of a polysilicon layer formed by the above processes is considered relatively superior as compared with polysilicon layers formed by conventional techniques because a polysilicon layer in accordance with this invention has a RMS roughness of about 0.1 nm to about 0.4 nm. That is, although the thickness of the polysilicon layer is required to be relatively thin, e.g., about 35 Å, the polysilicon layer may be uniformly formed due to the superior morphology realized in accordance with this invention.

The polysilicon layer thus formed is then planarized until the first isolation layer pattern 208 is exposed (as seen in FIG. 10) so as to form a polysilicon layer pattern 214. The polysilicon layer pattern 214 may serve as a floating gate for the memory device being fabricated.

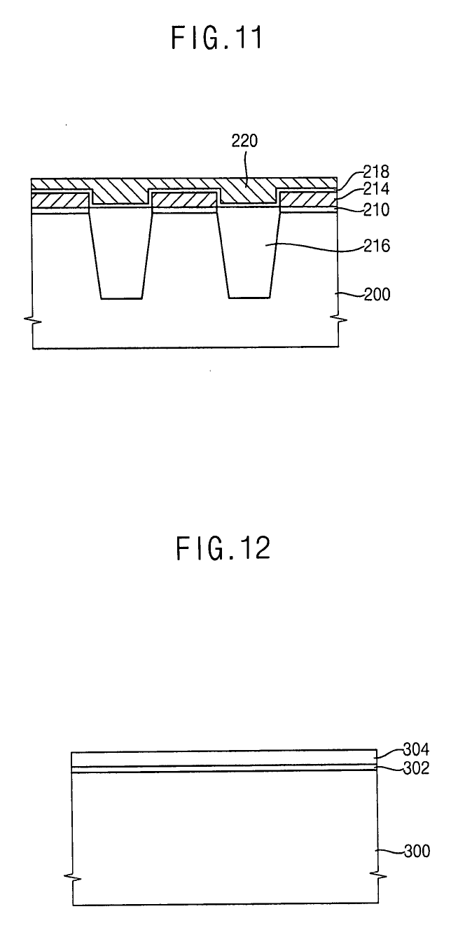

Referring now to FIG. 11, an upper portion of the first isolation layer pattern 208 is removed such that a sidewall of the polysilicon pattern 214 is exposed. Thus, the first isolation layer pattern 208 may be transformed into a second isolation layer pattern 216.

This step may be carried out such that tunnel oxide layer pattern 210 is not exposed when the second isolation layer pattern 216 is being formed.

A dielectric layer 218 and a control gate 220 are then sequentially formed on the second isolation layer pattern 216 and also on the polysilicon layer pattern 214. Processes of forming the dielectric layer 218 and the control gate 220 are substantially the same as those described and illustrated in connection with FIG. 6. Thus, any further explanation of these steps will be omitted.

Therefore, a planar-shaped non-volatile memory device may thus be formed comprising the tunnel oxide layer pattern 210, the floating gate 214 corresponding to the polysilicon layer pattern, the dielectric layer 218 and the control gate 220 that are sequentially formed on the semiconductor substrate 200. Such a memory device fabricated in accordance with this invention may be expected to demonstrate superior performance relative to comparable devices not prepared according to this invention.

FIGS. 12 to 19 are schematic cross-sectional views illustrating another method of manufacturing a non-volatile memory device in accordance with an exemplary embodiment of the present invention.

Referring to FIG. 12, a tunnel oxide layer 302 and an amorphous silicon layer 304 are formed on a semiconductor substrate 300.

The tunnel oxide layer 302 and amorphous silicon layer 304 are formed by processes substantially the same as those described above in connection with FIGS. 1 and 2. Thus, any further explanation of these steps will be omitted. The amorphous silicon layer 304 may advantageously have a thickness of about 35 Å to about 200 Å.

A polysilicon layer may thereafter be obtained from the amorphous silicon layer 304 by subsequent processes as described above. Such a polysilicon layer may be expected to demonstrate a superior thickness uniformity and a superior morphology, as indicated by the layer having an RMS roughness of about 0.1 nm to about 0.4 nm and even though the polysilicon layer has a relatively small thickness of about 35 Å to about 200 Å.

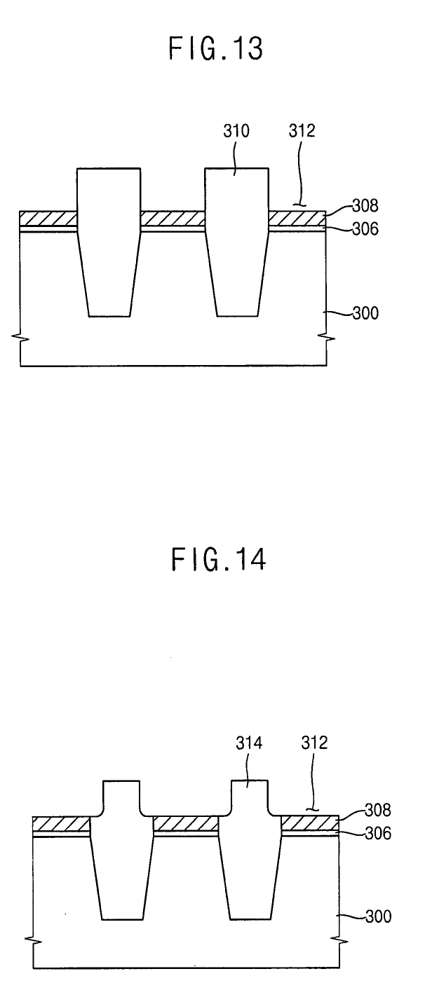

Referring now to FIG. 13, a mask layer (not shown) and a photoresist pattern are formed on the amorphous silicon layer 304 of FIG. 12.

The mask layer is then etched using the photoresist pattern as an etching mask so that a mask layer pattern may be formed. The amorphous silicon layer 304 and tunnel oxide layer 302 are then successively etched using the mask layer pattern as an etching mask. This processing step converts the tunnel oxide layer 302 (FIG. 12) into a tunnel oxide layer pattern 306 (FIG. 13).

In this invention embodiment, the amorphous silicon layer 304 may be transformed into the corresponding polysilicon layer (not shown) while the photoresist pattern and the mask layer pattern are being formed.

Accordingly, a tunnel oxide layer pattern 306 and a first polysilicon layer pattern 308 (obtained from the amorphous silicon layer) are successively formed on the semiconductor substrate 300.

A first opening (not shown) exposing a portion of the semiconductor substrate 300 is formed between portions of first polysilicon layer pattern 308 by an etching process. The portion of the semiconductor substrate 300 exposed through the first opening is etched to form a trench.

A thermal oxide layer and an insulating liner are then sequentially formed on an inner surface of the trench after the trench has been formed. Processes of forming the thermal oxide layer and the insulating liner are substantially the same as those described above in connection with FIG. 3. Thus, any further explanation of these steps will be omitted.

A first isolation layer (not shown) is then formed on the mask layer pattern and also so as to fill up the trench. The isolation layer preferably may include an oxide. The oxide may be selected from undoped silicate glass (USG), O₃-tetra-ethyl-ortho-silicate undoped silicate glass (O₃-TEOS USG), high density plasma (HDP) oxide, or similar materials, which are capable of effectively filling up a gap.

The first isolation layer is then planarized until the mask layer pattern is exposed, so that the first isolation layer may be transformed into a second isolation layer 310 (as seen in FIG. 13). Here, the second isolation layer 310 may correspond to a field region of the semiconductor device, while a portion of the semiconductor substrate 300 encompassing the second isolation layer 310 may correspond to an active region.

The mask layer pattern is then removed. Openings 312 exposing an upper surface of the first polysilicon pattern 308 are formed between upper portions of the second isolation layers 310 by removing the mask layer pattern.

Referring next to FIG. 14, an upper portion of the second isolation layer 310 (as seen in FIG. 13) that protrudes above the first polysilicon layer pattern 308 is isotropically etched so that the second isolation layer 310 may be transformed into a third isolation layer 314. A width of an upper portion of the third isolation layer 314 (as seen in FIG. 14) that protrudes from the first polysilicon layer pattern 308 may be smaller than a width of the upper portion of the second isolation layer 310 (as seen in FIG. 13).

Particularly, the upper portion of the second isolation layer 310 may be isotropically etched using a diluted hydrogen fluoride (HF) etching solution by a wet etching process because the second isolation layer 310 (which began as the first isolation layer) includes an oxide as described above. The diluted HF solution includes water and HF. In one illustrative embodiment, a ratio of water to HF may be about 200:1. The wet etching process may be performed using the diluted HF etching solution for an effective period of time, such as for about 80 seconds.

As a result of this step, the second isolation layer 310 may be transformed into the third isolation layer 314 having an upper portion narrower than a corresponding upper portion of the second isolation layer 310. A size of the field region may thereby decrease as a result of the second isolation layer 310 being transformed into the third isolation layer 314.

The first polysilicon layer pattern 308 has a relatively thin thickness of about 35 Å to about 200 Å. Although the first polysilicon layer pattern 308 is relatively thin, however, the tunnel oxide layer pattern 306 may experience little or no damage as a result of the diluted HF solution etching step because of the superior morphology and thickness uniformity of the first polysilicon layer pattern formed in accordance with this invention.

A cleaning process is then performed on the first polysilicon layer 308 so that a native oxide layer or contaminants may be removed from an exposed surface of the first polysilicon layer pattern 308.

Particularly, a native oxide layer may easily be formed at a surface portion of the first polysilicon layer pattern 308 since polysilicon has a relatively high degree of reactivity with respect to oxygen in the surrounding air. In addition, contaminants in the surrounding air may also easily become attached to the surface of the first polysilicon layer pattern 308. Thus, a cleaning process is performed to remove any such native oxide layer and/or contaminants from the first polysilicon layer pattern 308.

The cleaning process may comprise first and second cleaning steps that are sequentially performed. A standard clean 1 (SC1) solution including ammonium hydroxide, hydrogen peroxide and water and a first diluted HF cleaning solution are sequentially applied for about 20 seconds and about 480 seconds, respectively, during the first of the two cleaning steps. A ratio of water to HF in the first diluted HF cleaning solution may, for example, be about 100:1. A second diluted HF cleaning solution and the SC1 solution may be sequentially applied for about 180 seconds and about 300 seconds, respectively, during the second of the two cleaning steps. A ratio of water to HF in the second diluted HF cleaning solution may, for example, be about 200:1. The second cleaning step may be performed to also remove the native oxide layer from sidewalls of the first polysilicon layer pattern 308.

The third isolation layer 314 may also be partially removed by the above-described cleaning process.

In a case where the polysilicon layer pattern of a conventionally fabricated device that corresponds to first polysilicon layer pattern 308 has a structurally weak portion, the first and second diluted HF cleaning solutions may infiltrate to that polysilicon layer pattern while the cleaning process is being performed. However, the first polysilicon layer pattern 308 formed in accordance with this invention may not have any such structurally weak or vulnerable portion in exemplary embodiments of the present invention since the first polysilicon layer pattern 308 of this invention has a superior morphology and a superior thickness uniformity. Thus, the first and second diluted HF cleaning solutions generally would not deteriorate the first polysilicon layer pattern 308.

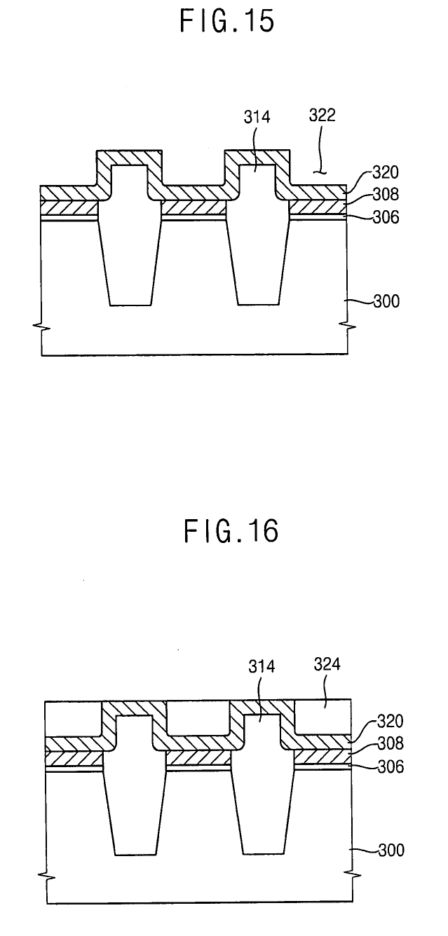

Referring now to FIG. 15, a second polysilicon layer 320 is formed on the first polysilicon layer pattern 308 and the third isolation layer 314. The second polysilicon layer 320 may be conformally formed on the first polysilicon layer pattern 308 and the third isolation layer 314 such that the openings 312 (as seen in FIG. 14) is partially filled with the second polysilicon layer 320 (as seen in FIG. 15).

The second polysilicon layer 320 may be formed by processes substantially the same as those performed to form the first polysilicon layer, as described above. Alternatively, the second polysilicon layer 320 may be performed by processes substantially different from those performed to form the first polysilicon layer. In addition, in some invention embodiments, the second polysilicon layer 320 may advantageously be a polysilicon layer doped with impurities.

As illustrated in FIGS. 15-19, a lower portion of the second polysilicon layer 320 may have a width larger than that of the first polysilicon layer pattern 308, since the upper portion of the second isolation layer 310 (as seen in FIG. 13) has been isotropically etched such that a width of the openings 312 become an enlarged opening 312 that is larger than the width of the first polysilicon layer pattern 308 (as seen by comparing FIGS. 13 and 14).

The second or enlarged opening 312 may be transformed into a second opening 322 (FIG. 15) by forming the second polysilicon layer 320 partially filling the enlarged opening 312 since the second polysilicon layer 320 is conformally formed on the first polysilicon layer pattern 308 and on the third isolation layer 314. A width of the second opening 322 may be smaller than a width of the enlarged opening 312 as seen in FIG. 14.

Referring now to FIG. 16, a sacrificial layer 324 is formed on the second polysilicon layer 320 so as to at least fill up the second opening 322. The sacrificial layer 324 may include an oxide. The sacrificial layer 324 may be formed using a material substantially the same as a material included in the isolation layer. Alternatively, the sacrificial layer 324 may be formed using a material substantially different from a material included in the isolation layer.

The sacrificial layer 324 is then planarized by performing a planarization process until the uppermost surfaces of second polysilicon layer 320 are exposed. The planarization process may be an etch-back process, a chemical mechanical polishing (CMP) process, or a similar or equivalent technique.

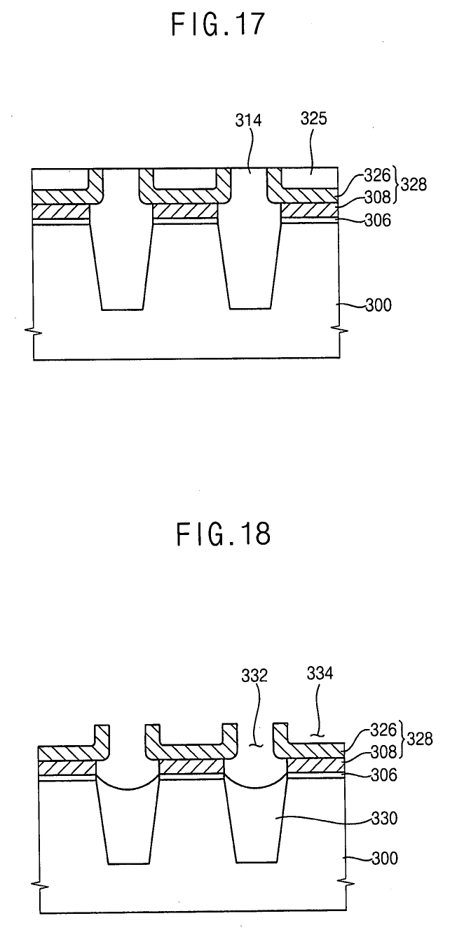

Referring next to FIG. 17, an exposed portion of the second polysilicon layer 320 is removed by an etching process so that the second polysilicon layer 320 may be transformed into a second polysilicon layer pattern 326 having a generally “U” shaped cross-section as seen in FIG. 17.

Floating gates 328 (comprised of adjacent portions of the first and second polysilicon layer patterns) spaced apart from one another may be formed on the tunnel oxide layer pattern 306 by the above-described etching process. The floating gate 328 includes the first polysilicon layer pattern 308 having a rectangular-shaped cross-section and the second polysilicon layer pattern 326 having a U-shaped cross-section. The first and second polysilicon layer patterns 308 and 326 correspond to upper and lower portions of the floating gate 328, respectively.

Referring next to FIG. 18, the remaining sacrificial layer 325 and an upper portion of the third isolation layer 314 (as seen in FIG. 17) are removed so that a fourth isolation layer pattern 330 may be formed.

As a result of these steps, a fourth opening 334 is defined over the floating gate 328 having the U-shaped cross-section; and a fifth opening 332 is defined over the fourth isolation layer pattern 330 by the floating gates 328.

Referring now to FIG. 19, a dielectric layer 336 is formed on the floating gate 328 and also on the fourth isolation layer 330. The dielectric layer 336 may be conformally formed on the floating gate 328 and the fourth isolation layer 330, and thus the dielectric layer 336 may partially fill the fourth opening 334 and the fifth opening 332. A control gate 338 is then formed on the dielectric layer 336.

The dielectric layer 336 and control gate 338 may be formed by processes substantially the same as those described in connection with FIG. 6. Thus, any further explanation of these steps will be omitted.

Accordingly, a non-volatile memory device including the tunnel oxide layer pattern 306, the U-shaped floating gate 328, the dielectric layer 336 and the control gate 338 may be formed on the semiconductor substrate 300. Such a memory device fabricated in accordance with this invention may be expected to demonstrate superior performance relative to comparable devices not prepared according to this invention.

Hereinafter, characteristics of a polysilicon layer formed using a silane (SiH₄) gas (which is outside the scope of this invention) and a polysilicon layer formed using a trisilane (Si₃H₈) gas in accordance with this invention will be compared.

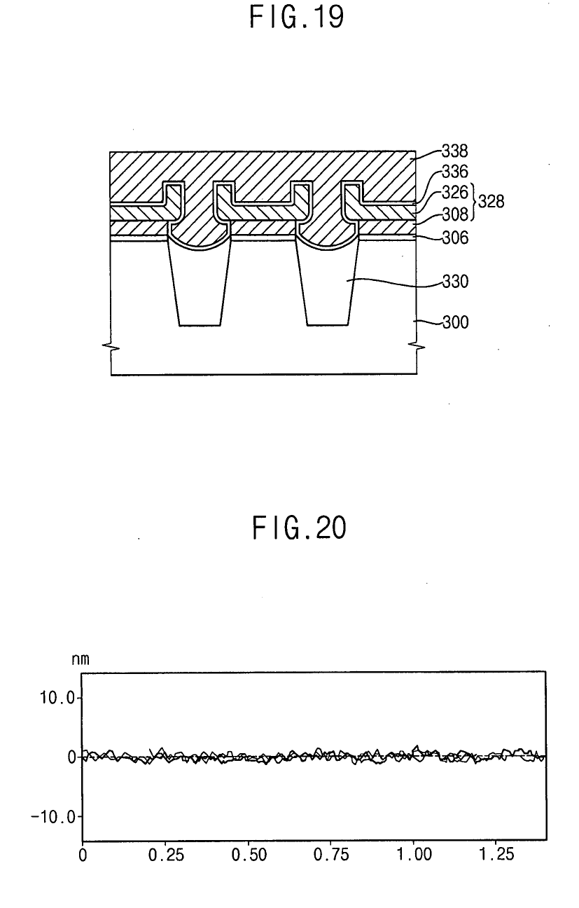

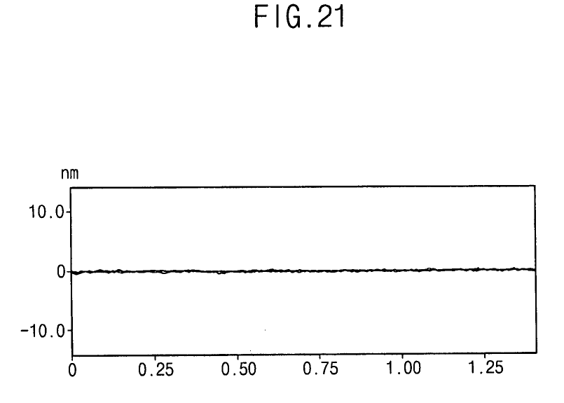

FIG. 20 is a graph illustrating an atomic force microscope (AFM) measurement result based on testing of a silane-based polysilicon layer formed using a silane (SiH₄) gas. FIG. 21 is a comparable graph illustrating an AFM measurement result based on testing of a trisilane-based polysilicon layer formed using a trisilane (Si₃H₈) gas.

An AFM may measure an RMS roughness of a surface of a thin film by using a repulsive force and an attractive force between atoms. The AFM may operate in a contact mode or a non-contact mode. The AFM result is not affected by an electrical characteristic of an object that is to be inspected. Thus, the AFM may be used to accurately measure the RMS roughness of a conductor, a semiconductor or a nonconductor.

In the graphs of FIGS. 20 and 21, a silane-based polysilicon layer having a thickness of about 250 Å was formed using a silane (SiH₄) gas. Here, a mean RMS roughness of the first polysilicon layer formed using the silane (SiH₄) gas was found to be about 0.98 nm. A maximum RMS roughness of the silane-based polysilicon layer was about 8.03 nm.

Another polysilicon layer having a thickness of about 250 Å was formed using a trisilane (Si₃H₈) gas. Here, a mean RMS roughness of the trisilane-based polysilicon layer formed using the trisilane (Si₃H₈) gas was about 0.26 nm. A maximum RMS roughness of the trisilane-based polysilicon layer was about 2.29 nm.

Thus, a morphology of the trisilane-based polysilicon layer formed using the trisilane (Si₃H₈) gas was superior to that of the silane-based polysilicon layer formed using the silane (SiH₄) gas.

As a result, a thickness of the trisilane-based polysilicon layer formed using the trisilane (Si₃H₈) gas was more effectively controlled than a thickness of the silane-based polysilicon layer formed using the silane (SiH₄) gas. In addition, the thickness of the trisilane-based polysilicon layer formed using the trisilane (Si₃H₈) gas was relatively uniform. Thus, the trisilane-based polysilicon layer was formed without having a structurally weak portion.

According to exemplary embodiments of the present invention, a polysilicon layer is formed on a tunnel oxide layer by using a trisilane (Si₃H₈) gas so that a thickness of the polysilicon layer may be effectively controlled. Thus, a uniform thickness of about 35 Å to about 200 Å may be effectively achieved when such a polysilicon layer is formed in this way.

In addition, the polysilicon layer formed using the trisilane (Si₃H₈) gas has a superior morphology. Thus, a cleaning solution or an etching solution may not infiltrate to the tunnel oxide layer positioned under the polysilicon layer.

Accordingly, a reliability of a non-volatile memory device employing a polysilicon layer in accordance with this invention as a floating gate may be improved.

The foregoing description is illustrative of the present invention and is not to be construed as limiting thereof. Although a few exemplary embodiments of the present invention have been described, those skilled in the art will readily appreciate that many modifications are possible in the exemplary embodiments without materially departing from the novel teachings and advantages of this invention. Accordingly, all such modifications are intended to be included within the scope of the present invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method of manufacturing a non-volatile memory device, the method comprising the steps of:
forming a tunnel oxide layer on a substrate;
forming a polysilicon layer having a thickness of about 35 Å to about 200 Å on the tunnel oxide layer by using a trisilane (Si₃H₈) gas;
patterning the tunnel oxide layer and the polysilicon layer to form a tunnel oxide layer pattern and a polysilicon layer pattern, respectively; and
subsequently forming a dielectric layer and a conductive layer corresponding to a control gate on the polysilicon layer pattern.

2. The method of claim 1, wherein a surface of the polysilicon layer has a root-mean-square roughness of about 0.1 nm to about 0.4 nm.

3. The method of claim 1, wherein the step of forming the polysilicon layer comprises:
forming an amorphous silicon layer on the tunnel oxide layer by a low pressure chemical vapor deposition process; and
crystallizing the amorphous silicon layer to form the polysilicon layer.

4. The method of claim 3, wherein the low pressure chemical vapor deposition process is performed at a temperature of about 400° C. to about 500° C. and at a pressure of about 100 mTorr to about 1,000 mTorr.

5. The method of claim 3, wherein the step of crystallizing the amorphous silicon layer is performed by thermally treating the amorphous silicon layer at a temperature of about 550° C. to about 900° C.

6. The method of claim 1, further comprising a step of providing a surface of the tunnel oxide layer with ozone water before the step of forming the polysilicon layer.

7. The method of claim 6, wherein the ozone water comprises deionized water and ozone, and a concentration of the ozone in the water is about 10 ppm to about 1,000 ppm.

8. The method of claim 1, wherein the step of patterning the tunnel oxide layer and the polysilicon layer to form the tunnel oxide layer pattern and the polysilicon layer pattern respectively comprises the steps of:
forming a mask layer pattern partially exposing the polysilicon layer on the polysilicon layer; and
etching the polysilicon layer, the tunnel oxide layer and the substrate to form a polysilicon layer pattern, a tunnel oxide layer pattern and a trench by using the mask layer pattern as an etching mask.

9. The method of claim 8, further comprising a step of forming an isolation layer so as to fill up the trench such that the isolation layer protrudes from a surface of the substrate.

10. The method of claim 9, further comprising a step of partially removing an upper portion of the isolation layer such that a sidewall of the polysilicon layer pattern is exposed.

11. The method of claim 9, further comprising the steps of:
removing the mask pattern to expose the polysilicon layer pattern;
partially removing the upper portion of the isolation layer by an isotropic etching process;
forming a second polysilicon layer on the isolation layer and the polysilicon layer pattern;
forming a second polysilicon layer pattern by removing a portion of the second polysilicon layer disposed higher than an upper surface of the isolation layer; and
forming an isolation layer pattern by removing an upper portion of the isolation layer such that sidewalls of the second polysilicon layer pattern are exposed.

12. The method of claim 11, wherein the isotropic etching process is performed using a diluted hydrogen fluoride solution.

13. The method of claim 11, further comprising a step of performing a cleaning process on the polysilicon layer pattern after the polysilicon layer pattern is exposed.

14. The method of claim 13, wherein the cleaning process is performed using a diluted hydrogen fluoride solution or a standard clean 1 solution including ammonium hydroxide, hydrogen peroxide and water.

15. A non-volatile memory device fabricated according to the method of claim 1.

16. A non-volatile memory device fabricated according to the method of claim 11.
